(19) United States
(12) Patent Application Publication
(10) Pub. No.: US 2022/0030709 A1
(43) Pub. Date: Jan. 27, 2022

(54) RESIN COMPOSITION FOR HIGH FREQUENCY SUBSTRATE AND METAL CLAD LAMINATE

(71) Applicant: NAN YA PLASTICS CORPORATION, TAIPEI (TW)

(72) Inventors: TE-CHAO LIAO, TAIPEI (TW); HAO-SHENG CHEN, TAIPEI (TW); HUNG-YI CHANG, TAIPEI (TW); CHIA-LIN LIU, TAIPEI (TW); CHIH-KAI CHANG, TAIPEI (TW)

(21) Appl. No.: 17/337,682

(22) Filed: Jun. 3, 2021

(30) Foreign Application Priority Data
Jul. 23, 2020 (TW) 109124865

(51) Int. Cl. H05K 1/03; C08K 3/36; B32B 15/08; C08L 71/12

(52) U.S. Cl. CPC H05K 1/0373; C08K 3/36; H05K 3/022; C08L 71/12; B32B 15/08

(57) ABSTRACT

A resin composition for a high frequency substrate and a metal clad laminate are provided. Based on a total weight of the resin composition for the high frequency substrate being 100 phr, the resin composition for the high frequency substrate includes: 20 phr to 70 phr of a polyphenylene ether resin, 5 phr to 40 phr of a polybutadiene resin, 5 phr to 30 phr of a bismaleimide resin, and 20 phr to 45 phr of a crosslinker. A glass transition temperature of the resin composition for the high frequency substrate is higher than or equal to 230° C. The metal clad laminate includes a substrate and a metal layer disposed on the substrate. The substrate is formed from the resin composition for the high frequency substrate.

### CROSS-REFERENCE TO RELATED PATENT APPLICATION

This application claims the benefit of priority to Taiwan Patent Application No. 109124865, filed on Jul. 23, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a resin composition for a high frequency substrate and a metal clad laminate, and more particularly to a resin composition for a high frequency substrate and a metal clad laminate which have a good adhesive force with a metal layer.

### BACKGROUND OF THE DISCLOSURE

A millimeter wave (mmWave) is an electromagnetic wave having a wavelength ranging from 1 mm to 10 mm and having a frequency ranging from 30 GHz to 300 GHz. The millimeter wave is also called an extremely high frequency (EHF). The millimeter wave is mainly used in electronic communications, military communications, scientific research, and medical treatments. In addition, the millimeter wave is a technique essential to development of a fifth generation wireless system (i.e., 5G wireless system). In order to meet the requirements of the 5G wireless system, high frequency transmission is undoubtedly a mainstream trend of development. Accordingly, the industry has devoted considerable effort to developing high frequency substrate materials that can be applied in the high frequency transmission (e.g., a frequency ranging between 6 GHz and 77 GHz), so as to allow a high frequency substrate to be used in base station antennas, satellite radars, automotive radars, wireless communication antennas, or power amplifiers.

In order to be applicable for high frequency transmission, the high frequency substrate should have a high dielectric constant (Dk) and a low dielectric dissipation factor (Df). The dielectric constant and the dielectric dissipation factor of the high frequency substrate are referred to as dielectric properties in the present disclosure.

Generally, the materials of the high frequency substrate include a polyphenylene ether resin having a low polarity and a polybutadiene resin having a low polarity. The low polarities of the polyphenylene ether resin and the polybutadiene resin can decrease water absorption of the high frequency substrate. In addition, an addition of the polybutadiene resin can further enhance the dielectric properties of the high frequency substrate. However, the high frequency substrate manufactured from the polyphenylene ether resin and the polybutadiene resin has problems of a low glass transition temperature (Tg) and a weak adhesive force with a metal layer. Accordingly, the high frequency substrate in a conventional technology has the anticipated dielectric properties but is unfavorable for processing. Moreover, the addition of the polybutadiene resin is prone to increase a viscosity of a resin composition, and a prepreg prepared from the resin composition is sticky and unfavorable for processing.

Therefore, a resin composition that enables the high frequency substrate to have good dielectric properties, an appropriate glass transition temperature, a good adhesive force with a metal layer, and good processability is still needed in the conventional technology.

### SUMMARY OF THE DISCLOSURE

In response to the above-referenced technical inadequacies, the present disclosure provides a resin composition for a high frequency substrate and a metal clad laminate.

In one aspect, the present disclosure provides a resin composition for a high frequency substrate. Based on a total weight of the resin composition being 100 parts per hundred resin (phr), the resin composition includes 20 phr to 70 phr of a polyphenylene ether resin, 5 phr to 40 phr of a polybutadiene resin, 5 phr to 30 phr of a bismaleimide resin, and 20 phr to 45 phr of a crosslinker. A glass transition temperature of the resin composition is higher than or equal to 230° C.

In certain embodiments, based on the total weight of the resin composition being 100 wt %, an amount of the polybutadiene resin is smaller than or equal to 25 wt %.

In certain embodiments, the polyphenylene ether resin has at least one modified group. The at least one modified group is selected from the group consisting of: a hydroxyl group, an amino group, a vinyl group, a styryl group, a methacrylate group, and an epoxy group.

In certain embodiments, the polyphenylene ether resin contains a first polyphenylene ether and a second polyphenylene ether. At least one modified group is provided at a molecular end of each of the first polyphenylene ether and the second polyphenylene ether. The at least one modified group is selected from the group consisting of: a hydroxyl group, an amino group, a vinyl group, a styryl group, a methacrylate group, and an epoxy group. The at least one modified group of the first polyphenylene ether is different from the at least one modified group of the second polyphenylene ether. A weight ratio of the first polyphenylene ether to the second polyphenylene ether ranges from 0.5 to 1.5.

In certain embodiments, the polybutadiene resin is selected from the group consisting of: a butadiene homopolymer, a styrene-butadiene copolymer, a styrene-butadiene-styrene copolymer, an acrylonitrile-butadiene copolymer, a hydrogenated styrene-butadiene-styrene copolymer, and a hydrogenated styrene-butadiene-isoprene-styrene copolymer.

In certain embodiments, the polybutadiene resin includes the styrene-butadiene copolymer. Based on a total weight of the polybutadiene resin being 100 wt %, the polybutadiene resin contains 20 wt % to 70 wt % of a vinyl group.

In certain embodiments, the polybutadiene resin includes the styrene-butadiene copolymer. Based on the total weight of the polybutadiene resin being 100 wt %, the polybutadiene resin contains 15 wt % to 40 wt % of a styryl group.

In certain embodiments, the bismaleimide resin includes 4,4′-diphenylmethane bismaleimide, an oligomer of phenylmethane maleimide, meta-phenylene bismaleimide, bisphenol A diphenylether bismaleimide, 3,3′-dimethyl-5,5′-diethyl-4,4′-diphenylmethane bismaleimide, 4-methyl-1,3-phenylene bismaleimide, 1,6-bismaleimide-(2,2,4-trimethyl)hexane, or any combination thereof.

In certain embodiments, a weight average molecular weight of the polyphenylene ether resin ranges from 1000 g/mol to 20000 g/mol.

In certain embodiments, a weight average molecular weight of the polybutadiene resin ranges from 1000 g/mol to 9000 g/mol.

In another aspect, the present disclosure provides a metal clad laminate.

The metal clad laminate includes a substrate and a metal layer disposed on the substrate. The substrate is formed from a resin composition for a high frequency substrate. Based on a total weight of the resin composition being 100 phr, the resin composition includes 20 phr to 70 phr of a polyphenylene ether resin, 5 phr to 40 phr of a polybutadiene resin, 5 phr to 30 phr of a bismaleimide resin, and 20 phr to 45 phr of a crosslinker. A glass transition temperature of the resin composition is higher than or equal to 230° C. A peeling strength of the metal clad laminate is higher than or equal to 6 lb/in.

In certain embodiments, a dielectric constant of the substrate ranges from 3.5 to 3.8 and a dielectric dissipation factor of the substrate ranges from 0.0035 to 0.0045.

Therefore, by virtue of “5 phr to 30 phr of the bismaleimide resin”, the resin composition for the high frequency substrate and the metal clad laminate provided by the present disclosure are capable of overcoming the problem of difficulty in processing due to stickiness of a prepreg, and the glass transition temperature of the resin composition for the high frequency substrate can be enhanced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a metal clad laminate according to one embodiment of the present disclosure; and

FIG. 2 is a schematic side view of the metal clad laminate according to another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

In order to solve the problems of a low glass transition temperature of a conventional high frequency substrate, a weak adhesive force between the conventional high frequency substrate and a metal layer, and poor processability of a conventional prepreg, the present disclosure provides a resin composition for a high frequency substrate. The resin composition of the present disclosure includes a bismaleimide resin to decrease a viscosity of the resin composition for the high frequency substrate. Even if the resin composition for the high frequency substrate also includes a polybutadiene resin, a prepreg prepared from said resin composition for the high frequency substrate can still maintain good processability. In addition, the high frequency substrate formed from the resin composition for the high frequency substrate of the present disclosure can have a good adhesive force with a metal layer and a high glass transition temperature.

### Resin Composition for High Frequency Substrate

The resin composition for the high frequency substrate of the present disclosure includes: 20 phr to 70 phr of a polyphenylene ether resin, 5 phr to 40 phr of a polybutadiene resin, 5 phr to 30 phr of a bismaleimide resin, and 20 phr to 45 phr of a crosslinker, based on a total weight of the resin composition being 100 phr. By controlling components and contents of the resin composition for the high frequency substrate, the resin composition for the high frequency substrate of the present disclosure can be used to manufacture the high frequency substrate that has good dielectric properties and a high glass transition temperature (higher than or equal to 230° C.). Further, the high frequency substrate can have a strong adhesive force (a peeling strength being higher than or equal to 6 lb/in) with a metal layer.

A weight average molecular weight of the polyphenylene ether resin ranges from 1000 g/mol to 20000 g/mol. Preferably, the weight average molecular weight of the polyphenylene ether resin ranges from 2000 g/mol to 10000 g/mol. More preferably, the weight average molecular weight of the polyphenylene ether resin ranges from 2000 g/mol to 2200 g/mol. When the weight average molecular weight of the polyphenylene ether resin is lower than 20000 g/mol, the polyphenylene ether resin has a high solubility to a solvent, thereby facilitating a preparation of the resin composition for the high frequency substrate.

In an exemplary embodiment, the polyphenylene ether resin can have at least one modified group. The modified group is selected from the group consisting of: a hydroxyl group, an amino group, a vinyl group, a styryl group, a methacrylate group, and an epoxy group. The modified group of the polyphenylene ether resin can provide an unsaturated bond to promote a proceeding of a crosslinking reaction, so that a material with a high glass transition temperature (Tg) and a high heat tolerance can be obtained. In the present embodiment, two opposite molecular ends of the polyphenylene ether resin each have one modified group, and the two modified groups are the same.

In an exemplary embodiment, the polyphenylene ether resin can contain various kinds of polyphenylene ether. For example, the polyphenylene ether resin can contain a first polyphenylene ether and a second polyphenylene ether. The first polyphenylene ether and the second polyphenylene ether respectively have at least one modified group at molecular ends. The at least one modified group is selected from the group consisting of: a hydroxyl group, an amino group, a vinyl group, a styryl group, a methacrylate group, and an epoxy group. The at least one modified group of the first polyphenylene ether is different from the at least one modified group of the second polyphenylene ether. Specifically, a weight ratio of the first polyphenylene ether to the second polyphenylene ether ranges from 0.5 to 1.5. Preferably, the weight ratio of the first polyphenylene ether to the second polyphenylene ether ranges from 0.75 to 1.25. More preferably, the weight ratio of the first polyphenylene ether to the second polyphenylene ether is 1.

For example, the first polyphenylene ether and the second polyphenylene ether can independently be polyphenylene ethers produced by Saudi Basic Industries Corporation (SABIC) as the model SA90 (the modified group at the two molecular ends being a hydroxyl group) and the model SA9000 (the modified group at the two molecular ends being a methacrylate group), or polyphenylene ethers produced by Mitsubishi Gas Chemical Co., Inc. (MGC) as the model OPE-2St (the modified group at the two molecular ends being a styryl group), as the model OPE-2EA (the modified group at the two molecular ends being a methacrylate group), and as the model OPE-2Gly (the modified group at the two molecular ends being an epoxy group). However, the present disclosure is not limited thereto. In a preferable embodiment, the first polyphenylene ether is one polyphenylene ether modified by a styryl group at the molecular ends, and the second polyphenylene ether is one polyphenylene ether modified by a methacrylate group at the molecular ends. The styryl group and the methacrylate group are nonpolar groups; hence, no polar group will be generated during or after hardening processes of the first polyphenylene ether and the second polyphenylene ether. Accordingly, the high frequency substrate can have good dielectric properties and low water absorption.

A weight average molecular weight of the polybutadiene resin of the present disclosure ranges from 1000 g/mol to 50000 g/mol, and the polybutadiene resin can be in a solid state or a liquid state at room temperature. Preferably, the weight average molecular weight of the polybutadiene resin ranges from 1000 g/mol to 12000 g/mol. More preferably, the weight average molecular weight of the polybutadiene resin ranges from 1000 g/mol to 9000 g/mol.

In an exemplary embodiment, the polybutadiene resin has at least one side chain containing a vinyl group. The side chain containing the vinyl group of the polybutadiene resin can provide an unsaturated bond to promote a proceeding of a crosslinking reaction. Accordingly, after the crosslinking reaction, a crosslink density and a heat tolerance of the resin composition for the high frequency substrate can be enhanced. Moreover, the side chain containing the alkene group can enhance flowability and a filling ability of the resin composition for the high frequency substrate.

In the present disclosure, the polybutadiene resin is a polymer formed from butadiene monomers, such as a butadiene homopolymer or a copolymer polymerized from butadiene and other monomers. For example, the copolymer polymerized from butadiene and other monomers can be: a styrene-butadiene copolymer (SBR), a styrene-butadiene-styrene copolymer (SBS), an acrylonitrile-butadiene copolymer, a hydrogenated styrene-butadiene-styrene copolymer, or a hydrogenated styrene-butadiene-isoprene-styrene copolymer. The unsaturated bond in the polybutadiene resin can promote a proceeding of a crosslinking reaction, so as to enhance the crosslink density of the resin composition for the high frequency substrate after the crosslinking reaction. However, the present disclosure is not limited thereto.

In a preferable embodiment, the polybutadiene resin is a styrene-butadiene copolymer, such as RICON® 100, RICON® 184, or RICON® 257 produced by Cray Valley. When the polybutadiene resin is a styrene-butadiene copolymer, based on a total weight of the polybutadiene resin being 100 wt %, the polybutadiene resin contains 15 wt % to 40 wt % of a styryl group. The polybutadiene resin contains 20 wt % to 70 wt % of a vinyl group.

The bismaleimide resin of the present disclosure can enhance the glass transition temperature of the high frequency substrate. For example, the bismaleimide resin can be 4,4′-diphenylmethane bismaleimide (such as BMI-1000, BMI-1000H, BMI-1000S, BMI-1100, or BMI-1100H produced by Daiwakasei Industry Co., LTD.), an oligomer of phenylmethane maleimide (such as BMI-2000 or BMI-2300 produced by Daiwakasei Industry Co., LTD.), meta-phenylene bismaleimide (such as BMI-3000 or BMI-3000H produced by Daiwakasei Industry Co., LTD.), bisphenol A diphenylether bismaleimide (such as BMI-4000 produced by Daiwakasei Industry Co., LTD.), 3,3′-dimethyl-5,5′-diethyl-4,4′-diphenylmethane bismaleimide (such as BMI-5100 produced by Daiwakasei Industry Co., LTD.), 4-methyl-1,3-phenylene bismaleimide (such as BMI-7000 or BMI-7000H produced by Daiwakasei Industry Co., LTD.), or 1,6-bismaleimide-(2,2,4-trimethyl)hexane (such as BMI-TMH produced by Daiwakasei Industry Co., LTD.). However, the present disclosure is not limited thereto.

It should be noted that an addition of the bismaleimide resin can enhance the glass transition temperature of the high frequency substrate, but can also decrease the dielectric properties of the high frequency substrate. In order to uphold both the glass transition temperature and the dielectric properties of the high frequency substrate, a weight ratio of the polyphenylene ether resin to the polybutadiene resin is controlled to range from 0.5 to 13, so as to maintain the dielectric properties of the high frequency substrate. Specifically, the weight ratio of the polyphenylene ether resin to the polybutadiene resin ranges from 0.8 to 3. Preferably, the weight ratio of the polyphenylene ether resin to the polybutadiene resin ranges from 0.85 to 2.

An addition of the crosslinker can enhance a crosslinking extent of the polyphenylene ether resin and the polybutadiene resin. In the present disclosure, the crosslinker can include an allyl group. For example, the crosslinker can be triallyl cyanurate (TAC), triallyl isocyanurate (TRIC), diallyl phthalate, divinylbenzene, triallyl trimellitate, or any combination thereof. Preferably, the crosslinker can be triallyl isocyanurate. However, the present disclosure is not limited thereto.

In addition to the polyphenylene ether resin, the polybutadiene resin, the bismaleimide resin, and the crosslinker mentioned previously, one of inorganic fillers, a compatibilizer, and a flame retardant can be optionally added into the resin composition for the high frequency substrate. It should be noted that the inorganic fillers, the compatibilizer, and the flame retardant are not necessary components of the resin composition.

An addition of the inorganic fillers can decrease the viscosity of the resin composition. For example, the inorganic fillers can be: silicon dioxide, titanium dioxide, aluminum hydroxide, aluminum oxide, magnesium oxide, calcium carbonate, boron oxide, calcium oxide, strontium titanate, barium titanate, calcium titanate, magnesium titanate, boron nitride, aluminum nitride, silicon carbide, cerium dioxide, or any combination thereof. However, the present disclosure is not limited thereto.

Silicon dioxide can be molten or crystalline silicon dioxide. In consideration of the dielectric properties of a metal clad laminate 1, silicon dioxide is preferably molten silicon dioxide. Titanium dioxide can be titanium dioxide with a rutile, an anatase, or a brookite configuration. In consideration of the dielectric properties of the metal clad laminate 1, titanium dioxide is preferably with a rutile configuration. A total weight of the inorganic fillers can be 0.4 to 2.5 times of the total weight of the resin composition for the high frequency substrate. In a preferable embodiment, the total weight of the inorganic fillers is 0.6 to 2.25 times of the total weight of the resin composition for the high frequency substrate.

The compatibilizer is a nonpolar polymer, which is helpful for enhancing a mixing effect between the polyphenylene ether resin and the polybutadiene resin. A state of the compatibilizer is changed in response to a molecular weight of the compatibilizer. When the compatibilizer contains 5 to 16 carbon atoms, the compatibilizer is usually in a liquid state. Once a quantity of carbon atoms of the compatibilizer increases, the compatibilizer may also be in a solid state.

In the present disclosure, the compatibilizer is a linear olefin polymer which is formed from a plurality of monomers arranged in a line after polymerization. However, structures of the monomers are not limited. In other words, the compatibilizer is a linear polymer, instead of being a branched polymer, a network polymer, or a macrocyclic polymer. Further, the compatibilizer is not the polybutadiene resin.

Specifically, the compatibilizer is an ethylene copolymer, a propylene copolymer, a methylstyrene copolymer, a cyclic olefin copolymer, or any combination thereof, but is not limited thereto.

In the present disclosure, the compatibilizer has at least one side chain which has 2 to 10 carbon atoms and contains a vinyl group. The side chain containing the vinyl group in the compatibilizer is helpful for the mixing of the polyphenylene ether resin and the polybutadiene resin. Water absorption, the dielectric constant, and the dielectric dissipation factor of the resin composition for the high frequency substrate can also be decreased due to the side chain containing the vinyl group in the compatibilizer. In a preferable embodiment, the side chain containing the vinyl group is selected from the group consisting of: a vinyl group, a propylene group, a styryl group, and any combination thereof. In a preferable embodiment, the compatibilizer does not contain a hydroxyl group. When the compatibilizer contains the hydroxyl group, the heat tolerance and the dielectric properties of the resin composition for the high frequency substrate are decreased, and the water absorption is increased.

An addition of the flame retardant can enhance a flame retardance of the high frequency substrate. For example, the flame retardant can be a phosphorus flame retardant or a brominated flame retardant.

The brominated flame retardant can be ethylene bistetrabromophthalimide, tetradecabromodiphenoxy benzene, decabromo diphenoxy oxide, or any combination, but is not limited thereto. For example, the brominated flame retardant can be SAYTEX® BT 93 W (ethylene bistetrabromophthalimide), SAYTEX® 120 (tetradecabromodiphenoxy benzene), SAYTEX® 8010 (ethane-1,2-bis(pentabromophenyl), SAYTEX® 102 (decabromo diphenoxy oxidd) produced by Albemarle Corporation. However, the present disclosure is not limited thereto.

The phosphorus flame retardant can be sulphosuccinic acid ester, phosphazene, ammonium polyphosphate, melamine polyphosphate, or melamine cyanurate. Sulphosuccinic acid ester includes triphenyl phosphate (TPP), tetraphenyl resorcinol bis(diphenylphosphate) (RDP), bisphenol A bis(diphenyl phosphate) (BADP), bisphenol A bis(dimethyl) phosphate (BBC), resorcinol bisdiphenylphosphate (a model of CR-733S produced by Daihachi Chemical Industry CO., LTD.), resorcinol-bis(di-2,6-dimethylphenyl phosphate) (a model of PX-200 produced by Daihachi Chemical Industry CO., LTD.). However, the present disclosure is not limited thereto.

In the present disclosure, a total weight of the flame retardant is 0.2 to 1.5 times to the total weight of the resin composition for the high frequency substrate. In a preferable embodiment, the total weight of the flame retardant is 0.3 to 1.25 times to the total weight of the resin composition for the high frequency substrate.

In addition, the present disclosure provides a metal clad laminate having good dielectric properties and a high peeling strength, which is thus suitable to be used for high frequency transmission.

### Metal Clad Laminate

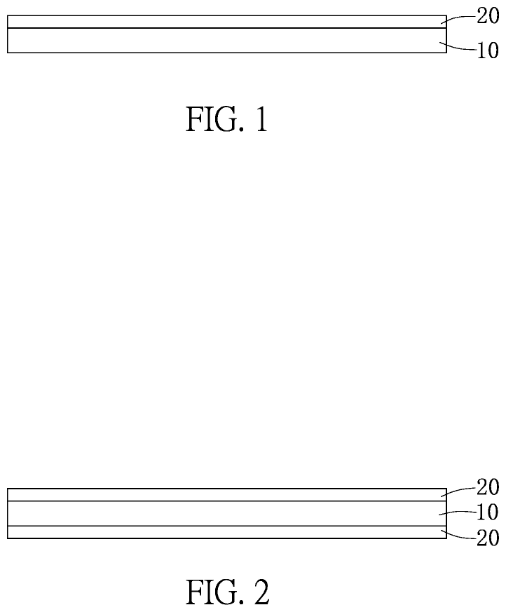

Referring to FIG. 1, FIG. 1 is a schematic side view of a metal clad laminate according to one embodiment of the present disclosure. The metal clad laminate of the present disclosure includes a substrate 10 and a metal layer 20 disposed on the substrate 10. A method for manufacturing the metal clad laminate includes steps of: forming the substrate 10 by using the aforesaid resin composition for the high frequency substrate and having the metal layer 20 disposed onto the substrate 10.

The substrate 10 is prepared by steps as follows. The aforesaid resin composition for the high frequency substrate is melted and uniformly mixed to form an immersing solution. A fiber cloth is immersed into the immersing solution. The immersed fiber cloth is taken out and then dried to form a prepreg. The prepreg is further processed to obtain the substrate 10.

In the present embodiment, the fiber cloth can be made from glass fibers, carbon fibers, KEVLAR® fibers, polyester fibers, quartz fibers, or any combination thereof. In a preferable embodiment, the fiber cloth is made from glass fibers, such as an electronic glass fiber cloth, an ultrathin electronic glass fiber cloth, or a low-dielectric electronic glass fiber cloth. However, the present disclosure is not limited thereto.

The metal layer 20 is configured by steps as follows. A metal foil is heat compressed onto the substrate 10 at a temperature from 180° C. to 260° C. and a pressure from 15 kg/cm² to 55 kg/cm², so as to dispose the metal layer 20 onto the substrate 10. Subsequently, the substrate 10 with the metal layer 20 are cooled to 150° C. at a rate of 1° C./min to 4° C./min, and then cooled from 150° C. to room temperature at a rate of 10° C./min, so that a crystallinity and a dimensional stability of the substrate 10 can be enhanced. However, the present disclosure is not limited thereto.

A quantity of the metal layer 20 can be adjusted according to types of the metal clad laminate. For example, when one metal layer 20 is disposed on the substrate 10, a single-sided metal clad laminate (FIG. 1) can be obtained. When two metal layers 20 are disposed on the substrate 10, a double-sided metal clad laminate (FIG. 2) can be obtained.

Referring to FIG. 2, FIG. 2 is a schematic side view of the metal clad laminate according to another embodiment of the present disclosure. The double-sided metal clad laminate can be manufactured by a method similar to the aforesaid method. Specifically, the metal layer 20 is disposed onto two opposite surfaces of the substrate 10. The substrate 10 and the metal layer 20 have structures similar to those mentioned previously, and are not reiterated herein.

In other embodiments, the metal layer 20 can further be patterned to form a circuit layer through etching and developing. Accordingly, a printed circuit board with good dielectric properties can be obtained and can be applied in high frequency transmission.

### [Experimental Data]

TABLE 1

| | | | | | | Comparative | |
|---|---|---|---|---|---|---|---|
| Example | | | | | | Example | |
| 1 | 2 | 3 | 4 | 5 | 6 | 1 | 2 |

Resin composition for high frequency substrate (phr)

| | | | | | | | | | |
|---|---|---|---|---|---|---|---|---|---|
| Polyphenylene | SA9000 | 28 | 16.8 | 9.4 | 0 | 28 | 28 | 28 | 28 |
| ether resin | OPE2St | 0 | 11.2 | 18.6 | 28 | 0 | 0 | 0 | 0 |
| | RI-257 | 0 | 0 | 0 | 0 | 0 | 14 | 0 | 0 |
| Polybutadiene | RI-100 | 14 | 14 | 14 | 14 | 7 | 0 | 14 | 0 |
| resin | B1000 | 0 | 0 | 0 | 0 | 0 | 0 | 0 | 14 |
| Bismaleimide | KI-70 | 7 | 7 | 7 | 7 | 21 | 7 | 0 | 7 |
| resin | | | | | | | | | |
| Crosslinker | TAIC | 21 | 21 | 21 | 21 | 14 | 21 | 28 | 21 |
| Filler (silicon | SS15V | 30 | 30 | 30 | 30 | 30 | 30 | 30 | 30 |
| dioxide) | | | | | | | | | |

Property measurement

| | | | | | | | | |
|---|---|---|---|---|---|---|---|---|
| Dielectric constant | 3.6 | 3.61 | 3.63 | 3.61 | 3.65 | 3.7 | 3.51 | 3.48 |
| (10 GHz) | | | | | | | | |
| Dielectric dissipation | 4.0 | 4.1 | 4.2 | 3.8 | 4.1 | 4.5 | 4.0 | 3.8 |
| factor × 10³ | | | | | | | | |
| (10 GHz) | | | | | | | | |
| Peeling strength (lb/in) | 6.8 | 7.1 | 7.2 | 8 | 8.4 | 7.6 | 4.9 | 5.6 |
| Glass transition | 238 | 258 | 263 | 265 | 273 | 248 | 198 | 215 |
| temperature (° C.) | | | | | | | | |

According to Table 1, the substrate 10 prepared from the resin composition for the high frequency substrate of the present disclosure has good dielectric properties. Specifically, the substrate 10 has a dielectric constant ranging from 3.5 to 3.8 and a dielectric dissipation factor ranging from 0.0035 to 0.0045. The dielectric constant and the dielectric dissipation factor of the substrate 10 are measured by a dielectric analyzer (model: HP Agilent E5071C) at 10 GHz.

The bismaleimide resin is added in the resin composition for the high frequency substrate of the present disclosure, so that the glass transition temperature of the substrate 10 can be enhanced. Accordingly, the glass transition temperature of the substrate 10 of the present disclosure is higher than 230° C. Specifically, the glass transition temperature of the substrate 10 ranges from 230° C. to 280° C. Preferably, the glass transition temperature of the substrate 10 ranges from 235° C. to 280° C.

In addition, the substrate 10 and the metal layer 20 have a strong connecting force. The peeling strength of the metal clad laminate is higher than 6 lb/in. Specifically, the peeling strength of the metal clad laminate ranges from 6 lb/in to 8.5 lb/in. Preferably, the peeling strength of the metal clad laminate ranges from 6.5 lb/in to 8.5 lb/in. The peeling strength of the metal clad laminate is measured according to IPC-TM-650-2.4.8 standard.

### Beneficial Effects of the Embodiments

In conclusion, by virtue of “5 phr to 30 phr of the bismaleimide resin”, the resin composition for the high frequency substrate and the metal clad laminate provided by the present disclosure are capable of overcoming the problem of difficulty in processing due to stickiness of the prepreg, and the glass transition temperature of the resin composition for the high frequency substrate can be enhanced.

Further, by virtue of “an amount of the polybutadiene resin being lower than or equal to 25 wt % based on the total weight of the resin composition for the high frequency substrate being 100 wt %”, the resin composition for the high frequency substrate and the metal clad laminate provided by the present disclosure can uphold both good dielectric properties and processability at the same time.

Further, by virtue of “the polyphenylene ether resin having at least one modified group”, the resin composition for the high frequency substrate and the metal clad laminate provided by the present disclosure promote the proceeding of the crosslinking reaction and enhance the glass transition temperature.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A resin composition for a high frequency substrate, the resin composition, based on a total weight thereof being 100 phr, comprising:
20 phr to 70 phr of a polyphenylene ether resin;
5 phr to 40 phr of a polybutadiene resin;
5 phr to 30 phr of a bismaleimide resin; and
20 phr to 45 phr of a crosslinker;
wherein a glass transition temperature of the resin composition is higher than or equal to 230° C.

2. The resin composition according to claim 1, wherein, based on the total weight of the resin composition being 100 wt %, an amount of the polybutadiene resin is smaller than or equal to 25 wt %.

3. The resin composition according to claim 1, wherein the polyphenylene ether resin has at least one modified group, and the at least one modified group is selected from the group consisting of: a hydroxyl group, an amino group, a vinyl group, a styryl group, a methacrylate group, and an epoxy group.

4. The resin composition according to claim 1, wherein the polyphenylene ether resin contains a first polyphenylene ether and a second polyphenylene ether, at least one modified group is provided at a molecular end of each of the first polyphenylene ether and the second polyphenylene ether, and the at least one modified group is selected from the group consisting of: a hydroxyl group, an amino group, a vinyl group, a styryl group, a methacrylate group, and an epoxy group; wherein the at least one modified group of the first polyphenylene ether is different from the at least one modified group of the second polyphenylene ether, and a weight ratio of the first polyphenylene ether to the second polyphenylene ether ranges from 0.5 to 1.5.

5. The resin composition according to claim 1, wherein the polybutadiene resin is selected from the group consisting of: a butadiene homopolymer, a styrene-butadiene copolymer, a styrene-butadiene-styrene copolymer, an acrylonitrile-butadiene copolymer, a hydrogenated styrene-butadiene-styrene copolymer, and a hydrogenated styrene-butadiene-isoprene-styrene copolymer.

6. The resin composition according to claim 5, wherein the polybutadiene resin includes the styrene-butadiene copolymer, and based on a total weight of the polybutadiene resin being 100 wt %, the polybutadiene resin contains 20 wt % to 70 wt % of a vinyl group.

7. The resin composition according to claim 5, wherein the polybutadiene resin includes the styrene-butadiene copolymer, and based on a total weight of the polybutadiene resin being 100 wt %, the polybutadiene resin contains 15 wt % to 40 wt % of a styryl group.

8. The resin composition according to claim 1, wherein the bismaleimide resin includes 4,4′-diphenylmethane bismaleimide, an oligomer of phenylmethane maleimide, meta-phenylene bismaleimide, bisphenol A diphenylether bismaleimide, 3,3′-dimethyl-5,5′-diethyl-4,4′-diphenylmethane bismaleimide, 4-methyl-1,3-phenylene bismaleimide, 1,6-bismaleimide-(2,2,4-trimethyl)hexane, or any combination thereof.

9. The resin composition according to claim 1, wherein a weight average molecular weight of the polyphenylene ether resin ranges from 1000 g/mol to 20000 g/mol.

10. The resin composition according to claim 1, wherein a weight average molecular weight of the polybutadiene resin ranges from 1000 g/mol to 9000 g/mol.

11. A metal clad laminate, comprising:
a substrate formed from a resin composition for a high frequency substrate, wherein, based on a total weight of the resin composition being 100 phr, the resin composition includes 20 phr to 70 phr of a polyphenylene ether resin, 5 phr to 40 phr of a polybutadiene resin, 5 phr to 30 phr of a bismaleimide resin, and 20 phr to 45 phr of a crosslinker, and wherein a glass transition temperature of the resin composition is higher than or equal to 230° C.; and
a metal layer disposed on the substrate;
wherein a peeling strength of the metal clad laminate is higher than or equal to 6 lb/in.

12. The metal clad laminate according to claim 11, wherein a dielectric constant of the substrate ranges from 3.5 to 3.8, and a dielectric dissipation factor of the substrate ranges from 0.0035 to 0.0045.
